(19) United States
(12) Patent Application Publication
(10) Pub. No.: US 2024/0324207 A1
(43) Pub. Date: Sep. 26, 2024

(54) SEMICONDUCTOR STORAGE DEVICE AND MANUFACTURING METHOD THEREOF

(71) Applicant: Kioxia Corporation, Tokyo (JP)

(72) Inventors: Takuya YAMADA, Yokkaichi Mie (JP); Osamu ARISUMI, Kuwana Mie (JP)

(73) Assignee: Kioxia Corporation, Tokyo (JP)

(21) Appl. No.: 18/588,547

(22) Filed: Feb. 27, 2024

(30) Foreign Application Priority Data
Mar. 22, 2023 (JP) 2023-045982

(51) Int. Cl. H10B 43/27; H01L 23/00; H01L 25/065; H01L 25/18; H10B 80/00

(52) U.S. Cl. CPC H10B 43/27; H01L 24/08; H01L 25/0657; H01L 25/18; H10B 80/00; H01L 2224/08145; H01L 2924/1431; H01L 2924/14511

(57) ABSTRACT

A semiconductor storage device includes a first conductive layer. A stacked body includes a plurality of electrode films and a plurality of first insulating films alternately stacked in a first direction of the first conductive layer, in the first direction. A columnar body includes a semiconductor layer penetrating the stacked body in the first direction. A second insulating film is provided on an inner wall of a slit penetrating the stacked body in the first direction. Wiring is provided at an inside of the second insulating film in the slit, is electrically separated from the plurality of electrode films by the second insulating film, and is electrically connected to the first conductive layer. A third insulating film extends in a first surface intersecting the first direction in the first conductive layer. The third insulating film protrudes from the inner wall of the slit toward the wiring.

### CROSS-REFERENCE TO RELATED APPLICATION

This application is based upon and claims the benefit of priority from Japanese Patent Application No. 2023-045982, filed Mar. 22, 2023, the entire contents of which are incorporated herein by reference.

### FIELD

Embodiments described herein relate generally to a semiconductor storage device and a manufacturing method thereof.

### BACKGROUND

A NAND-type flash memory, which includes a three-dimensional memory cell array in which a plurality of memory cells are three-dimensionally arranged, is under development. Such a memory cell array includes a stacked body in which a plurality of word lines are stacked and a slit penetrating the stacked body. Wiring connected to a source layer below the memory cell array is provided in the slit.

The slit may be significantly widened in a source layer direction in the vicinity of the source layer. In this case, a large void may occur in the wiring and the interconnect resistance may increase.

### DESCRIPTION OF THE DRAWINGS

FIG. 1 is a cross-sectional view showing a configuration example of a semiconductor storage device according to a first embodiment.

FIG. 2 is a schematic plan view showing a stacked body.

FIG. 3 is a schematic cross-sectional view illustrating a memory cell having a three-dimensional structure.

FIG. 4 is a schematic cross-sectional view illustrating a memory cell having a three-dimensional structure.

FIG. 5A is a cross-sectional view showing a configuration example of a columnar body, a slit, and wiring in the slit according to the first embodiment.

FIG. 5B is a perspective view showing a configuration example of the columnar body, the slit, and the wiring in the slit of FIG. 5A.

FIG. 6 is a cross-sectional view showing a configuration example of the columnar body, the slit, and the wiring in the slit according to the first embodiment.

FIG. 7 is a cross-sectional view showing an example of a manufacturing method of the semiconductor storage device according to the first embodiment.

FIG. 8 is a cross-sectional view showing the example of the manufacturing method, following FIG. 7.

FIG. 9 is a cross-sectional view showing the example of the manufacturing method, following FIG. 8.

FIG. 10 is a cross-sectional view showing the example of the manufacturing method, following FIG. 9.

FIG. 11 is a cross-sectional view showing the example of the manufacturing method, following FIG. 10.

FIG. 12 is a cross-sectional view showing the example of the manufacturing method, following FIG. 11.

FIG. 13 is a cross-sectional view of the columnar body and the slit according to a comparative example.

### DETAILED DESCRIPTION

Embodiments provide a semiconductor storage device and a manufacturing method thereof, which can reduce the occurrence of a large void in a wiring in a slit and reduce an increase in the interconnect resistance.

In general, according to one embodiment, the semiconductor storage device includes a first conductive layer. A stacked body includes a plurality of electrode films and a plurality of first insulating films alternately stacked in a first direction of the first conductive layer, in the first direction. A columnar body includes a semiconductor layer penetrating the stacked body in the first direction. A second insulating film is provided on an inner wall of a slit penetrating the stacked body in the first direction. Wiring is provided at an inside of the second insulating film in the slit, is electrically separated from the plurality of electrode films by the second insulating film, and is electrically connected to the first conductive layer. A third insulating film extends in a first surface intersecting the first direction in the first conductive layer. The third insulating film protrudes from the inner wall of the slit toward the wiring.

Hereinafter, embodiments of the present disclosure will be described with reference to the drawings. The present embodiment does not limit the present disclosure. The drawings are schematic or conceptual. In the specification and drawings, the same elements are denoted by the same reference numerals.

### First Embodiment

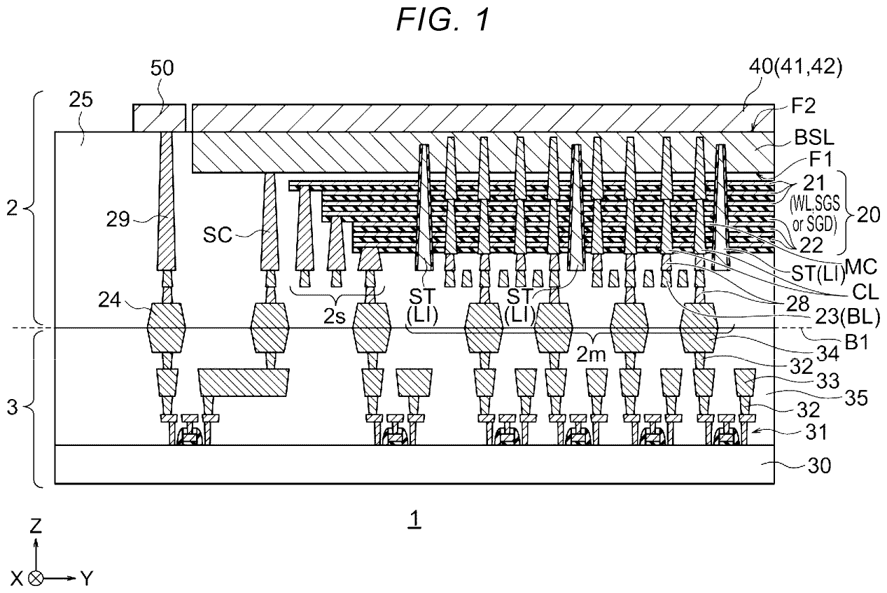

FIG. 1 is a cross-sectional view showing a configuration example of a semiconductor storage device 1 according to a first embodiment. Hereinafter, a stacking direction of the stacked body 20 is referred to as a Z direction. A direction intersecting, for example, orthogonal to the Z direction is referred to as a Y direction. A direction intersecting, for example, orthogonal to each of the Z direction and the Y direction is referred to as an X direction.

The semiconductor storage device 1 includes an array chip 2 having a memory cell array and a CMOS chip 3 having a CMOS circuit. The array chip 2 and the CMOS chip 3 are bonded to each other at a bonding surface B1 and are electrically connected to each other via wiring joined at the bonding surface. FIG. 1 shows a state in which the array chip 2 is mounted on the CMOS chip 3.

The CMOS chip 3 includes a substrate 30, a transistor 31, a via 32, wiring 33 and 34, and an interlayer insulating film 35.

The substrate 30 is, for example, a semiconductor substrate such as a silicon substrate. The transistor 31 is an NMOS or PMOS transistor provided on the substrate 30. The transistor 31 configures, for example, the CMOS circuit that controls the memory cell array of the array chip 2. The transistor 31 is an example of a plurality of logic circuits. A semiconductor element such as a resistor element or a capacitor element other than the transistor 31 may be formed on the substrate 30.

The via 32 electrically connects the transistor 31 and the wiring 33 or the wiring 33 and the wiring 34. The wirings 33 and 34 form a multilayer wiring structure in the interlayer insulating film 35. The wiring 34 is embedded in the interlayer insulating film 35 and is exposed substantially flush with the surface of the interlayer insulating film 35. The wirings 33 and 34 are electrically connected to the transistor 31 and the like. For the via 32 and the wirings 33 and 34, for example, a low-resistance metal such as copper or tungsten is used. The interlayer insulating film 35 covers and protects the transistor 31, the via 32, and the wirings 33 and 34. For the interlayer insulating film 35, for example, an insulating film such as a silicon oxide film is used.

The array chip 2 includes a stacked body 20, a columnar body CL, a slit ST (LI), a source layer BSL, a metal layer 40, a contact 29, and a bonding pad 50.

The stacked body 20 is provided above the transistor 31 and is positioned in the Z direction with respect to the substrate 30. The stacked body 20 includes a plurality of electrode films 21 and a plurality of insulating films 22 alternately stacked along the Z direction. The stacked body 20 configures the memory cell array. For the electrode film 21, for example, a conductive metal such as tungsten is used. For the insulating film 22, for example, an insulating film such as a silicon oxide film is used. The insulating film 22 insulates the electrode films 21 from each other. That is, the plurality of electrode films 21 are stacked in an insulated state. The number of stacked layers of each of the electrode films 21 and the insulating films 22 is optionally determined. The insulating film 22 may be, for example, a porous insulating film or an air gap.

One or the plurality of electrode films 21 at an upper end and a lower end of the stacked body 20 in the Z direction function as a source side select gate SGS and a drain side select gate SGD, respectively. The electrode film 21 between the source side select gate SGS and the drain side select gate SGD functions as a word line WL. The word line WL is a gate electrode of the memory cell MC. The drain side select gate SGD is a gate electrode of a drain side select transistor. The source side select gate SGS is provided in lower region of the stacked body 20. The drain side select gate SGD is provided in an upper region of the stacked body 20. The upper region refers to a region of the stacked body 20 on a side close to the CMOS chip 3, and the lower region refers to a region of the stacked body 20 on a side far from the CMOS chip 3 (a side close to the metal layer 40).

The semiconductor storage device 1 has a plurality of memory cells MC connected in series between a source side select transistor and a drain side select transistor. A structure in which the source side select transistor, the memory cell MC, and the drain side select transistor are connected in series is called a “memory string” or a “NAND string”. The memory string is connected to a bit line BL via the via 28, for example. The bit line BL is the wiring 23 provided below the stacked body 20 and extending in the X direction (paper surface direction in FIG. 1).

A plurality of columnar bodies CL are provided in the stacked body 20. The columnar body CL extends in the stacking direction (Z direction) of the stacked body in the stacked body 20 to penetrate the stacked body 20, and is provided from the via 28 connected to the bit line BL to the source layer BSL. The internal structure of the columnar body CL will be described later. In the present embodiment, the columnar body CL has a high aspect ratio, and thus is formed in two stages in the Z direction. However, the columnar body CL may be one stage.

In addition, a plurality of slits ST (LI) are provided in the stacked body 20. The slit ST (LI) extends in the X direction and penetrates the stacked body 20 in the stacking direction (Z direction) of the stacked body 20. The slit ST (LI) is filled with an insulating film such as a silicon oxide film, and the insulating film is formed in a plate shape. The slit ST (LI) electrically separates the electrode film 21 of the stacked body 20. Alternatively, the insulating film such as a silicon oxide film may be coated on the inner wall of the slit ST (LI), and a conductive material may be embedded inside the insulating film. In this case, the conductive material also functions as source wiring LI reaching the source layer BSL. That is, the slit ST may be the source wiring LI that is electrically separated from the electrode film 21 of the stacked body 20 forming the memory cell array and electrically connected to the source layer BSL. The slit is also referred to as ST (LI).

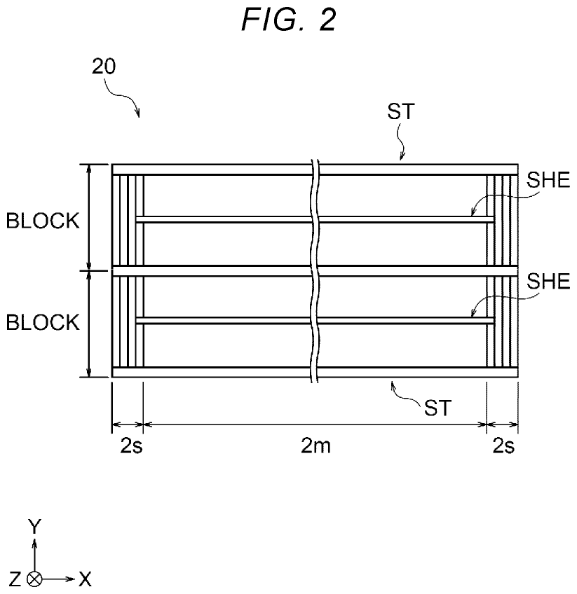

The source layer BSL is provided on the stacked body 20. The source layer BSL is an example of a first semiconductor layer. The source layer BSL corresponds to the stacked body 20. The source layer BSL has a first surface F1 and a second surface F2 opposite to the first surface F1. The stacked body 20 (memory cell array) is provided on a first surface F1 side of the source layer BSL, and the metal layer 40 is provided on a second surface F2 side. The metal layer 40 includes a source line 41 and a power supply line 42. The source line 41 and the power supply line 42 will be described in detail later. The source layer BSL is commonly connected to one end of the plurality of columnar bodies CL, and applies a common source voltage to the plurality of columnar bodies CL in the same memory cell array 2m. That is, the source layer BSL functions as a common source electrode of the memory cell array 2m. For the source layer BSL, for example, a conductive material such as doped polysilicon is used. For the metal layer 40, a metal material having a lower resistance than the source layer BSL, such as copper, aluminum, or tungsten, is used. A stepped portion 2s of the electrode film 21 connects the contact to each electrode film 21. The stepped portion 2s will be described later with reference to FIG. 2.

Meanwhile, the bonding pad 50 is provided in a region on the stacked body 20 where the source layer BSL is not provided. The bonding pad 50 is an example of the first electrode. The bonding pad 50 is connected to a metal wire (not shown) or the like and receives power supply from the outside of the semiconductor storage device 1. The bonding pad 50 is connected to the transistor 31 of the CMOS chip 3 via the contact 29, the wiring 24, and the wiring 34. Therefore, the external power supply supplied from the bonding pad 50 is supplied to the transistor 31. For the contact 29, for example, a low-resistance metal such as copper or tungsten is used.

In the present embodiment, the array chip 2 and the CMOS chip 3 are separately formed and bonded to each other at the bonding surface B1. Therefore, the transistor 31 is not provided in the array chip 2. In addition, the stacked body 20 (memory cell array) is not provided in the CMOS chip 3. Both the transistor 31 and the stacked body 20 are on the first surface F1 side of the source layer BSL. The transistor 31 is on a side opposite to the second surface F2 on which the metal layer 40 is provided.

The via 28, the wiring 23, and the wiring 24 are provided below the stacked body 20. The wirings 23 and 24 are embedded in the interlayer insulating film 25 and are exposed substantially flush with the surface of the interlayer insulating film 25. The wirings 23 and 24 are electrically connected to the semiconductor body 210 and the like of the columnar body CL. For the via 28, the wiring 23, and the wirings 24, for example, a low-resistance metal such as copper or tungsten is used. The interlayer insulating film 25 covers and protects the stacked body 20, the via 28, the wiring 23, and the wiring 24. For the interlayer insulating film 25, for example, an insulating film such as a silicon oxide film is used.

The interlayer insulating film 25 and the interlayer insulating film 35 are bonded to each other at the bonding surface B1, and the wiring 24 and the wiring 34 are also joined to each other substantially flush on the bonding surface B1. Accordingly, the array chip 2 and the CMOS chip 3 are electrically connected to each other via the wiring 24 and the wiring 34.

FIG. 2 is a schematic plan view showing the stacked body 20. The stacked body 20 includes the stepped portion 2s and the memory cell array 2m. The stepped portion 2s is provided at an edge portion of the stacked body 20. The memory cell array 2m is sandwiched or surrounded by the stepped portion 2s. The slit ST (LI) is provided from the stepped portion 2s at one end of the stacked body 20 to the stepped portion 2s at the other edge of the stacked body 20 through the memory cell array 2m. The slit ST (LI) extends in the X direction in the X-Y surface. A slit SHE is provided in at least the memory cell array 2m. The slit SHE is shallower than the slit ST (LI) and extends substantially parallel to the slit ST (LI). The slit SHE electrically separates the electrode film 21 for each drain side select gate SGD.

A portion of the stacked body 20 sandwiched between two slits ST (LI) shown in FIG. 2 is called a block (BLOCK). The block configures, for example, the minimum unit of data erasing. The slit SHE is provided in the block. The stacked body 20 between the slit ST (LI) and the slit SHE is called a finger. The drain side select gate SGD is divided into each finger. Therefore, at the time of writing and reading data, one finger in the block can be set to a selected state by the drain side select gate SGD.

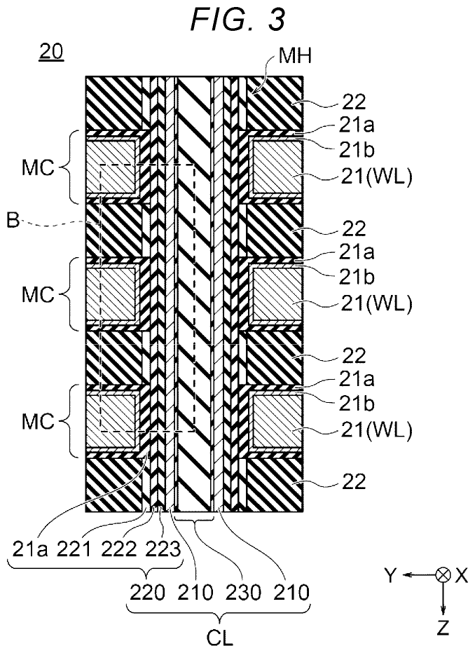

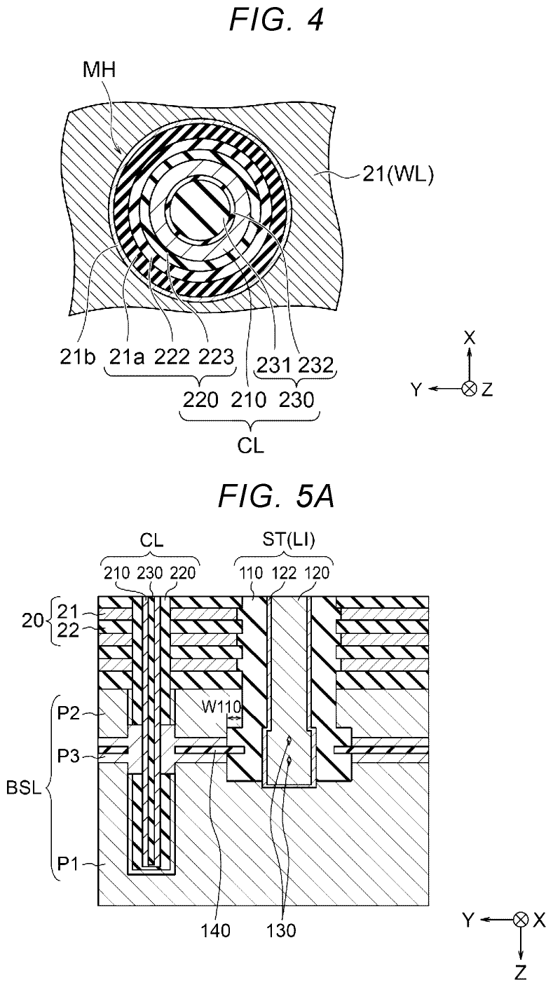

Each of FIG. 3 and FIG. 4 is a schematic cross-sectional view illustrating a memory cell having a three-dimensional structure. Each of the plurality of columnar bodies CL is provided in a memory hole MH provided in the stacked body 20. The memory hole MH penetrates the stacked body 20 from the upper end of the stacked body 20 along the Z direction. Along with this, each columnar body CL penetrates the stacked body 20 from the upper end of the stacked body 20 along the Z direction and is provided throughout the inside of the stacked body 20 and the inside of the source layer BSL. Each of the plurality of columnar bodies CL includes the semiconductor body 210, a memory film 220, and a core layer 230. The columnar body CL includes the core layer 230 provided at a center portion thereof, the semiconductor body (semiconductor member) 210 provided around the core layer 230, and the memory film (charge storage member) 220 provided around the semiconductor body 210. The semiconductor body 210 extends in the stacking direction (Z direction) in the stacked body 20. The semiconductor body 210 is electrically connected to the source layer BSL. The memory film 220 is provided between the semiconductor body 210 and the electrode film 21 and has a charge trapping unit. The plurality of columnar bodies CL, each of which is selected from each of the fingers, are commonly connected to one bit line BL via the via 28 of FIG. 1. Each of the columnar bodies CL is provided in a region of the memory cell array 2m, for example.

As shown in FIG. 4, the shape of the memory hole MH in the X-Y plane is, for example, a circle or an ellipse. A block insulating film 21a constituting a part of the memory film 220 may be provided between the electrode film 21 and the insulating film 22. The block insulating film 21a is, for example, a silicon oxide film or a metal oxide film. An example of the metal oxide is aluminum oxide. A barrier film 21b may be provided between the electrode film 21 and the insulating film 22 and between the electrode film 21 and the memory film 220. For example, when the electrode film 21 is made of tungsten, for example, a stacked structure film of titanium nitride and titanium is selected as the barrier film 21b. The block insulating film 21a reduces the back tunneling of charges from the electrode film 21 to the memory film 220 side. The barrier film 21b improves the adhesion between the electrode film 21 and the block insulating film 21a.

The shape of the semiconductor body 210 as the semiconductor member is, for example, a cylindrical shape having a bottom. The semiconductor body 210 has a cylindrical shape to surround the periphery of the core layer 230. For the semiconductor body 210, for example, polysilicon is used. The semiconductor body 210 is, for example, undoped silicon. In addition, the semiconductor body 210 may be p-type silicon. The semiconductor body 210 is a channel of each of the drain side select transistor STD, the memory cell MC, and the source side select transistor STS. One end of the plurality of semiconductor bodies 210 in the same memory cell array 2m is electrically commonly connected to the source layer BSL.

A portion of the memory film 220 other than the block insulating film 21a is provided between the inner wall of the memory hole MH and the semiconductor body 210. The shape of the memory film 220 is, for example, a cylindrical shape. The plurality of memory cells MC have a storage region between the semiconductor body 210 and the electrode film 21 serving as the word line WL, and are stacked in the Z direction. The memory film 220 includes, for example, a cover insulating film 221, a charge trapping film 222, and a tunnel insulating film 223. Each of the semiconductor body 210, the charge trapping film 222, and the tunnel insulating film 223 extends in the Z direction.

The cover insulating film 221 is provided between the insulating film 22 and the charge trapping film 222. The cover insulating film 221 is provided around the charge trapping film 222. The cover insulating film 221 includes, for example, a silicon oxide. The cover insulating film 221 protects the charge trapping film 222 from being etched when the sacrificial film (not shown) is replaced with the electrode film 21 (replacement step). The cover insulating film 221 may be removed from between the electrode film 21 and the memory film 220 in the replacement step. In this case, as shown in FIGS. 3 and 4, for example, the block insulating film 21a is not provided between the electrode film 21 and the charge trapping film 222. In addition, when the replacement step is not used for the formation of the electrode film 21, the cover insulating film 221 may not be provided.

The charge trapping film 222 is provided between the block insulating film 21a and the cover insulating film 221, and the tunnel insulating film 223. The charge trapping film 222 has a cylindrical shape to surround the tunnel insulating film 223. The charge trapping film 222 includes, for example, silicon nitride and has trap sites that trap charges in the film. A portion of the charge trapping film 222 sandwiched between the electrode film 21 serving as the word line WL and the semiconductor body 210 serves as the charge trapping unit and configures the storage region of the memory cell MC. A threshold voltage of the memory cell MC changes depending on the presence or absence of the charge in the charge trapping unit or the amount of the charge trapped in the charge trapping unit. As a result, the memory cell MC stores information.

The tunnel insulating film 223 is provided between the semiconductor body 210 and the charge trapping film 222. The tunnel insulating film 223 has a cylindrical shape to surround the periphery of the semiconductor body 210. The tunnel insulating film 223 includes, for example, silicon oxide, or silicon oxide and silicon nitride. The tunnel insulating film 223 is a voltage barrier between the semiconductor body 210 and the charge trapping film 222. For example, when the electron is injected from the semiconductor body 210 into the charge trapping unit (write operation) and when the hole is injected from the semiconductor body 210 into the charge trapping unit (erasing operation), the electron and the hole each pass through (tunnel) the voltage barrier of the tunnel insulating film 223.

The core layer 230 fills an internal space of the cylindrical semiconductor body 210. The shape of the core layer 230 is, for example, a columnar shape. The core layer 230 includes, for example, silicon oxide and is insulating. As shown in FIG. 4, the core layer 230 includes a plurality of insulating films 231 and 232.

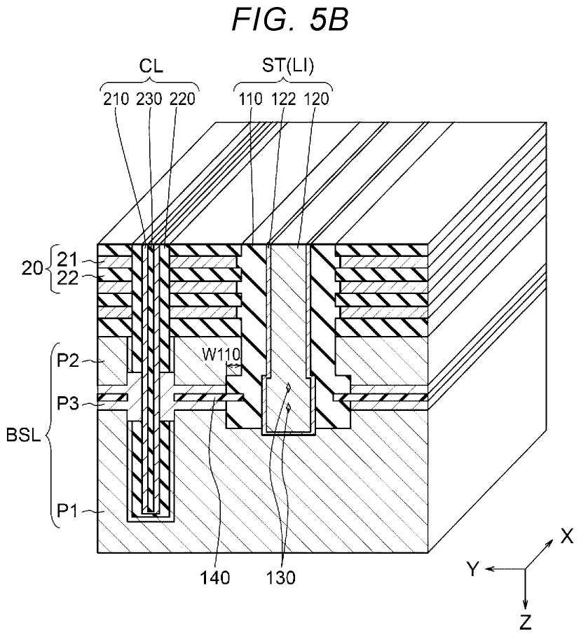

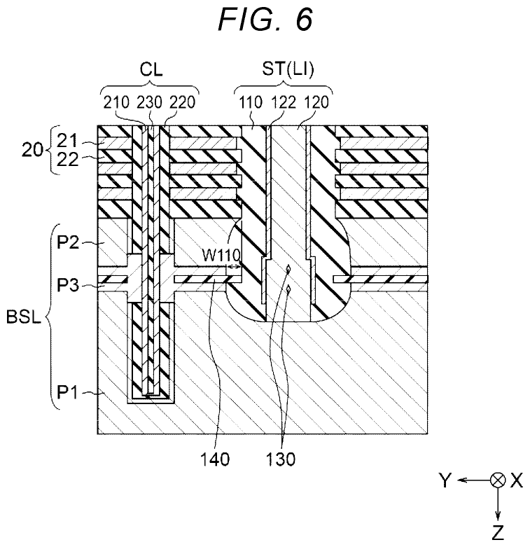

FIGS. 5A and 6 are cross-sectional views showing a configuration example of the columnar body, the slit, and the wiring in the slit according to the first embodiment. FIG. 5B is a perspective view showing a configuration example of the columnar body, the slit, and the wiring in the slit of FIG. 5A. FIGS. 5A, 5B, and 6 show the lower end portion of the columnar body CL and the slit ST on the source layer BSL side. The cross sections of FIGS. 5A and 6 are cross sections perpendicular to the direction (X direction) in which the slit ST extends in the X-Y plane. In FIGS. 5A, 5B, and 6, the Z direction is shown upside down as compared with the Z direction in FIG. 1. Hereinafter, the description will proceed with the −Z direction as the upward direction.

In the present embodiment, the stacked body 20 including the plurality of electrode films 21 and the plurality of insulating films 22 alternately stacked is provided above the source layer BSL (in the −Z direction). The columnar body CL penetrates the stacked body 20 in the Z direction and reaches the source layer BSL.

The source layer BSL includes a stacked film of first to third conductive materials P1 to P3. For the first to third conductive materials P1 to P3, for example, a conductive material such as doped polysilicon is used. The third conductive material P3 is sandwiched between the first conductive material P1 and the second conductive material P2. The first to third conductive materials P1 to P3 are electrically integrated to constitute the source layer BSL.

At the height of the third conductive material P3, the memory film 220 of the columnar body CL is removed, and the third conductive material P3 is in direct contact with the semiconductor body 210. Accordingly, the semiconductor body 210 is electrically connected to the source layer BSL.

In the third conductive material P3, the insulating film 140 extends in the X-Y surface intersecting the Z direction (for example, orthogonal to the Z direction). For the insulating film 140, a film containing at least silicon and oxygen (for example, a silicon oxide film) is used. In addition, when the insulating film 140 contains etching residues of other silicon oxide films, a film containing at least silicon, oxygen, and fluorine (for example, a fluorine-containing silicon oxide film) is used for the insulating film 140.

The slit ST penetrates the stacked body 20 in the Z direction and reaches the source layer BSL. Further, the slit ST penetrates the second and third conductive materials P2 and P3 and reaches the first conductive material P1. An insulating film 110 is provided on the inner wall of the slit ST. For the insulating film 110, for example, an insulating material such as a silicon oxide film is used. In a plan view in the Z direction, the slit ST extends in the X direction as shown in FIG. 5B.

The wiring 120 is provided inside the insulating film 110 in the slit ST. The wiring 120 is electrically separated from the electrode film 21 by the insulating film 110 and is electrically connected to the source layer BSL. The wiring 120 is electrically connected to the first conductive material P1.

Here, the insulating film 140 provided in the third conductive material P3 protrudes from the inner wall of the slit ST toward the wiring 120 in the X-Y surface. The tip end portion of the insulating film 140 protrudes from the inner wall of the slit ST and is present in the insulating film 110. However, the insulating film 140 does not reach the wiring 120.

A bottom portion of the slit ST has a substantially rectangular shape in a cross section in a direction perpendicular to the X direction. Therefore, the width of the slit ST in the Y direction in the vicinity of the height of the third conductive material P3 is wider by W110×2 than the width of the slit ST in the Y direction in the other portion, and the side surface of the slit ST has a step by the width W110 at the height of the third conductive material P3. Further, the side surface of the bottom portion of the slit ST extends in a substantially perpendicular direction (Z direction) with respect to the X-Y surface in the cross section perpendicular to the X direction. Preferably, the side surface of the bottom portion of the slit ST has an inclination of ±10% or less from the Z direction. The insulating film 140 protrudes toward the inside of the slit ST and is embedded in the insulating film 110.

In the cross section perpendicular to the X direction, at least two voids 130 are provided in the wiring 120 at the bottom portion of the slit ST in the Z direction. The two voids 130 are provided one in the +Z direction and one the −Z direction at the height of the third conductive material P3.

In FIG. 6, the bottom portion of the slit ST has a substantially circular shape in the cross section in the direction perpendicular to the X direction. Similar to the slit ST in FIG. 5, the width of the slit ST in the Y direction in the vicinity of the height of the third conductive material P3 is wider by W110×2 than the width of the slit ST in the Y direction in the other portion. In FIG. 6, the side surface of the slit ST is arcuate and does not have a step except for the portion of the insulating film 140. The insulating film 140 protrudes toward the inside of the slit ST and is embedded in the insulating film 110. The void 130 is provided in the same manner as the void 130 shown in FIG. 5.

As shown in FIGS. 5 and 6, the bottom portion of the slit ST has a substantially rectangular or substantially circular shape in a cross section in a direction perpendicular to the X direction, and the insulating film 140 protrudes toward the inside of the slit ST at the height of the third conductive material P3. Therefore, the width of the bottom portion of the slit ST in the Y direction is not widened at the height of the third conductive material P3, and is recessed inward of the slit ST by the amount of protrusion of the insulating film 140. Therefore, the insulating film 110 and the wiring 120 do not spread so much at the height of the third conductive material P3, and the void 130 is also relatively small. Therefore, according to the present embodiment, an increase in the resistance of the wiring 120 (that is, the source wiring LI) can be reduced.

In addition, depending on the perpendicularity of the bottom portion side surface of the slit ST, the protrusion amount of the insulating film 140, and the like, the void 130 may not be formed. In that case, the effect of reducing the resistance increase of the wiring 120 is further enhanced.

Next, a manufacturing method of the semiconductor storage device 1 according to the present embodiment will be described.

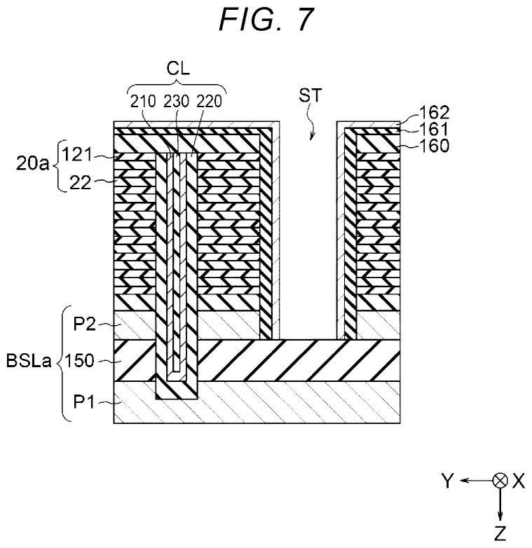

FIGS. 7 to 12 are cross-sectional views showing an example of a manufacturing method of the semiconductor storage device 1 according to the first embodiment. In FIGS. 7 to 12, the columnar body CL and the slit SL (LI) are shown in an arranged manner for convenience, one by one.

First, the first conductive material P1, a first sacrificial film 150, and the second conductive material P2 are stacked on the substrate (not shown) to form a first stacked body BSLa. For the first and second conductive materials P1 and P2, for example, doped polysilicon is used. For the first sacrificial film 150, for example, a silicon nitride film is used.

In the −Z direction of the first stacked body BSLa, a plurality of sacrificial films 121 and the plurality of insulating films 22 are alternately stacked in the Z direction to form a second stacked body 20a. For the insulating film 22, for example, an insulating material such as a silicon oxide film is used. For the sacrificial film 121, for example, an insulating material such as a silicon nitride film is used.

Next, the memory hole MH penetrating the inside of the second stacked body 20a in the Z direction is formed. The cover insulating film 221, the charge trapping film 222, and the tunnel insulating film 223 are stacked in this order on the inner wall of the memory hole MH. As a result, a structure of the memory film 220 is obtained. For the cover insulating film 221, for example, an insulating material such as a silicon oxide film is used. For the charge trapping film 222, for example, an insulating material such as a silicon nitride film is used. For the tunnel insulating film 223, for example, an insulating material such as a silicon oxide film is used. Next, the semiconductor body 210 is formed on the inner wall of the tunnel insulating film 223 in the memory hole MH. For the semiconductor body 210, for example, a semiconductor material such as doped polysilicon is used. Next, the material of the core layer 230 is embedded inside the semiconductor body 210 in the memory hole MH. For the core layer 230, for example, an insulating material such as a silicon oxide film is used. As a result, the columnar body CL shown in FIG. 7 penetrates the second stacked body 20a in the Z direction and reaches the first conductive material P1 of the first stacked body BSLa.

Next, the insulating film 160 is deposited on the second stacked body 20a, and then the slit ST penetrating the second stacked body 20a in the Z direction is formed using a lithography technique and an etching technique. The slit ST also penetrates the second conductive material P2 and reaches a first sacrificial film 150. The slit ST extends in the X direction in the X-Y surface (refer to FIG. 2). For the insulating film 160, for example, an insulating film such as a silicon oxide film is used.

Next, the insulating film 161 is deposited on the insulating film 160 and the inner wall of the slit ST. For the insulating film 161, for example, an insulating film such as a silicon oxide film is used. Next, a spacer film 162 is deposited on the insulating film 161. For the spacer film 162, for example, polysilicon is used. As a result, the structure shown in FIG. 7 is obtained.

Next, the first sacrificial film 150 is isotropically etched and removed via the slit ST. As a result, a space 151 is provided between the first conductive material P1 and the second conductive material P2 where the first sacrificial film 150 was present. The side surface of the bottom portion of the columnar body CL is exposed in the space 151.

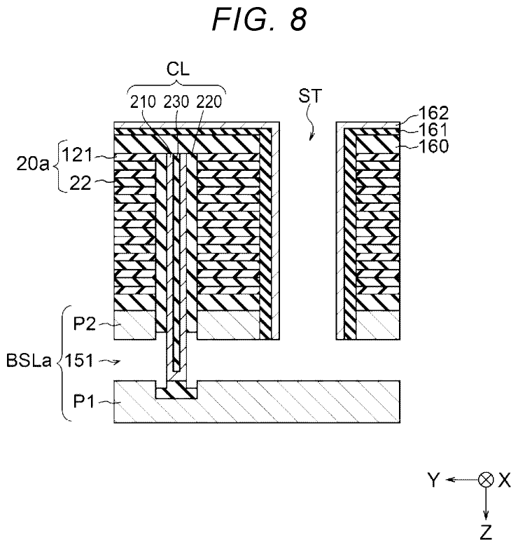

Next, the memory film 220 exposed in the space 151 is removed to expose the semiconductor body 210. As a result, the structure shown in FIG. 8 is obtained.

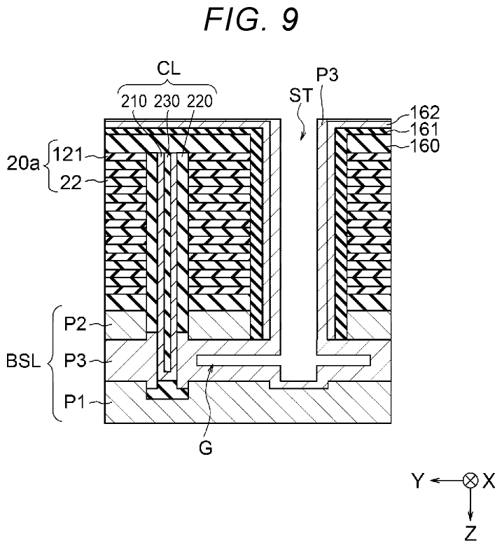

Next, the third conductive material P3 is deposited on the inner wall of the space 151 and the inner wall of the slit ST using an atomic layer deposition (ALD) method, a chemical vapor deposition (CVD) method, or the like. For the third conductive material P3, for example, a conductive material such as doped polysilicon is used. At this time, as shown in FIG. 9, the third conductive material P3 is deposited to be embedded in the space 151, and the gap G extending in the X-Y surface is left centering around the slit ST. The third conductive material P3 is in direct contact with the semiconductor body 210 of the columnar body CL.

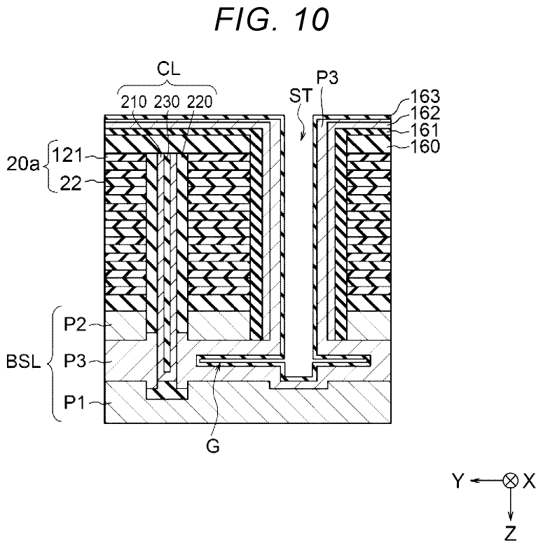

Next, the surface of the third conductive material P3 in the space 151 and the slit ST is oxidized to form the insulating film 163. The insulating film 163 is formed on the inner wall of the slit ST and the gap G of the third conductive material P3 between the first conductive material P1 and the second conductive material P2. For the insulating film 163, for example, a film containing silicon and oxygen (for example, a silicon oxide film) formed by oxidizing the surface of the third conductive material P3 such as doped polysilicon is used. As a result, the structure shown in FIG. 10 is obtained.

Next, the insulating film 163 on the inner wall of the slit ST is etched back using a chemical dry etching (CDE) method or the like. At this time, the etching gas is unlikely to reach the gap G, and the insulating film 163 in the gap G is left without being etched. Therefore, the insulating film 163 formed on the inner wall of the slit ST is removed while the insulating film 163 formed in the gap G of the third conductive material P3 is left.

Next, the third conductive material P3 and the spacer film 162 on the inner wall of the slit ST are etched back using a CDE method or the like. Since the insulating film 163 on the inner wall of the gap G is left, the insulating film 163 serves as a mask, and the third conductive material P3 in the gap G is not etched. In addition, the gap G is narrower than the slit ST, and a by-product (etching residue) 164 generated by etching is likely to be left. Therefore, the inside of the insulating film 163 of the gap G may be filled with the by-product 164. The by-product 164 is, for example, a film containing silicon, oxygen, and fluorine (for example, a fluorine-containing silicon oxide film) or the like. The insulating film 163 and the by-product 164 are left as the insulating film 140.

The third conductive material P3 and the spacer film 162 in the slit ST are removed by etching back the third conductive material P3 and the spacer film 162, and the insulating film 161 is exposed. The insulating film 161 is an insulating film (for example, a silicon oxide film) resistant to the etching gas of the third conductive material P3 and the spacer film 162 (for example, polysilicon). Therefore, the inner wall of the slit ST is protected by the insulating film 161.

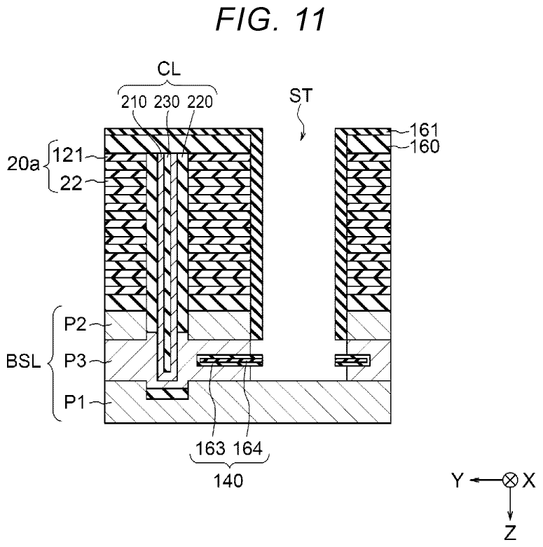

Meanwhile, in the bottom portion of the slit ST, the third conductive material P3 is exposed from the insulating film 161 and is etched to some extent in the Y direction. As a result, as shown in FIG. 11, the third conductive material P3 is recessed in the Y direction at the bottom portion of the slit ST, and the insulating film 140 protrudes from the third conductive material P3 toward the inside of the slit ST. That is, the third conductive material P3 is left in the space 151 between the first conductive material P1 and the second conductive material P2, and the third conductive material P3 on the inner wall of the slit ST is removed. Accordingly, the insulating film 140 protrudes from the third conductive material P3 toward the inside of the slit ST.

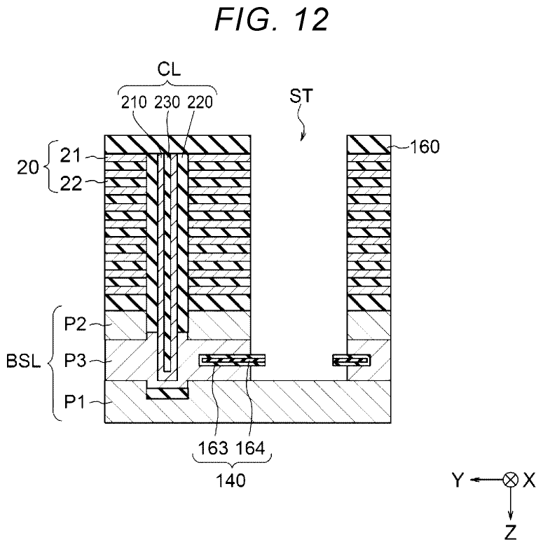

Next, the insulating film 161 is removed, and the second sacrificial film 121 and the cover insulating film 221 are removed via the slit ST. The barrier film 21b and the block insulating film 21a are thinly formed on the inner wall of the space after the sacrificial film 121 is removed, and the material (for example, tungsten) of the electrode film 21 is further embedded in the space. As a result, the sacrificial film 121 of the stacked body 20 is replaced (replaced) with the electrode film 21, and the structure shown in FIG. 12 is obtained.

Next, the insulating film 110 is formed on the inner wall of the slit ST. Further, a barrier metal 122 is formed on the inside of the insulating film 110 in the slit, and the wiring 120 is further embedded in the inside of the barrier metal 122. For the barrier metal 122, for example, titanium or titanium nitride is used. For the wiring 120, for example, a conductive metal such as tungsten is used. As a result, the structure shown in FIG. 5 or 6 is obtained.

Next, a multilayer wiring layer (not shown) and the like are formed on the columnar body CL. As a result, the array chip 2 is completed.

Next, as shown in FIG. 1, the CMOS chip 3 formed in a separate step is bonded to the array chip 2.

Next, the source layer BSL is exposed using the CMP method. The metal layer 40 and the bonding pad 50 are formed on the source layer BSL. As a result, the semiconductor storage device 1 according to the present embodiment is completed.

According to the present embodiment, when the third conductive material P3 and the spacer film 162 on the inner wall of the slit ST are etched back, the insulating film 140 is provided in the gap G of the third conductive material P3 at the bottom portion of the slit ST. Therefore, the etching gas does not enter the gap G, and the third conductive material P3 is not etched from the gap G. Accordingly, the width of the bottom portion of the slit ST in the Y direction is not widened at the height of the third conductive material P3, and is recessed inward of the slit ST by the amount of protrusion of the insulating film 140. As a result, the gap G does not widen in the third conductive material P3, and the insulating film 110 is hardly formed in the gap G. The void 130 is also relatively small. Therefore, according to the present embodiment, an increase in the resistance of the wiring 120 (that is, the source wiring LI) can be reduced.

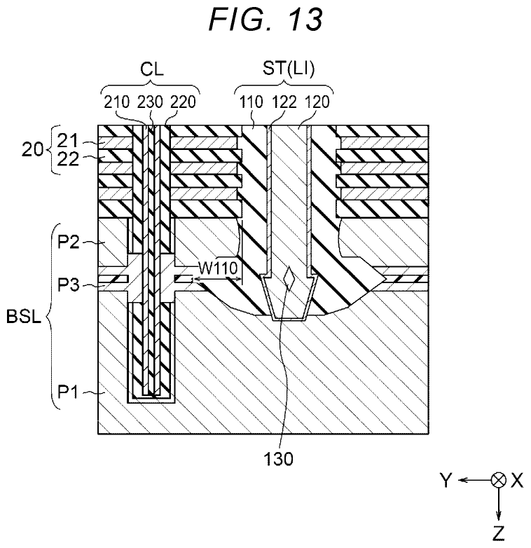

Meanwhile, FIG. 13 is a cross-sectional view of the columnar body CL and the slit SL (LI) according to a comparative example. When the insulating film 140 is not provided in the gap G in the third conductive material P3, in the etching step of the third conductive material P3 and the spacer film 162 in the slit ST, the etching gas enters the gap G, and the third conductive material P3 is etched from the gap G. As a result, as shown in FIG. 13, the width W110 of the insulating film 110 in the Y direction at the bottom portion of the slit ST is widened at the height of the third conductive material P3. The gap G is widened in the third conductive material P3, and the insulating film 110 is embedded in the gap G. The void 130 is also relatively large. Therefore, the resistance of the wiring 120 (that is, the source wiring LI) increases. Further, when the width W110 of the insulating film 110 is widened and the insulating film 110 comes into contact with the columnar body CL, the contact resistance between the semiconductor body 210 and the source layer BSL also increases, which adversely affects the characteristics of the memory cell MC.

Meanwhile, according to the present embodiment, the insulating film 140 is provided in the gap G of the third conductive material P3 at the bottom portion of the slit ST. As a result, the gap G does not widen in the third conductive material P3, and the void 130 is also relatively small. Therefore, an increase in the resistance of the wiring 120 can be reduced. The characteristics of the memory cell MC are also hardly affected.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first conductive layer;
a stacked body including a plurality of electrode films and a plurality of first insulating films alternately stacked in a first direction;
a columnar body including a semiconductor layer penetrating the stacked body in the first direction;
a second insulating film disposed on an inner wall of a slit penetrating the stacked body in the first direction;
wiring disposed at an inside of the second insulating film in the slit, electrically separated from the plurality of electrode films using the second insulating film, and electrically connected to the first conductive layer; and
a third insulating film extending in a first surface intersecting the first direction in the first conductive layer,
wherein the third insulating film protrudes from the inner wall of the slit toward the wiring.

2. The semiconductor storage device according to claim 1,
wherein a tip end portion of the third insulating film protruding from the inner wall of the slit is in the second insulating film and does not extend to the wiring.

3. The semiconductor storage device according to claim 1,
wherein the slit extends in a second direction in the first surface, and
a bottom portion of the slit has a substantially rectangular shape or substantially circular shape in a cross section perpendicular to the second direction.

4. The semiconductor storage device according to claim 1,
wherein the slit extends in a second direction in the first surface, and
a side surface of a bottom portion of the slit is substantially perpendicular to the first surface in a cross section perpendicular to the second direction.

5. The semiconductor storage device according to claim 1,
wherein the slit extends in a second direction in the first surface, and
at least two voids are provided in the wiring at a bottom portion of the slit in a cross section perpendicular to the second direction.

6. The semiconductor storage device according to claim 1,
Wherein the third insulating film contains at least silicon and oxygen.

7. The semiconductor storage device according to claim 1,
Wherein the third insulating film contains at least silicon, oxygen, and fluorine.

8. The semiconductor storage device according to claim 1,
wherein the first conductive layer is doped polysilicon.

9. A manufacturing method of a semiconductor storage device, the method comprising:
forming a first stacked body by stacking a first conductive material, a first sacrificial film, and a second conductive material in a first direction;
forming a second stacked body by alternately stacking a plurality of second sacrificial films and a plurality of first insulating films in the first direction;
forming a columnar body including a semiconductor layer penetrating the second stacked body in the first direction;
forming a slit penetrating the second stacked body in the first direction;
removing the first sacrificial film via the slit;
forming a third conductive material on an inner wall of the slit and on an inner wall of a space between the first conductive material and the second conductive material where the first sacrificial film is present;
forming a third insulating film on the inner wall of the slit and in a gap of the third conductive material between the first conductive material and the second conductive material;
removing the third insulating film formed on the inner wall of the slit while leaving the third insulating film formed in the gap of the third conductive material;
removing the third conductive material formed on the inner wall of the slit while leaving the third conductive material in the space between the first conductive material and the second conductive material to cause the third insulating film to protrude from the third conductive material toward an inside of the slit;
forming a second insulating film on the inner wall of the slit; and
providing a wiring in an inside of the second insulating film in the slit.

10. The semiconductor storage device according to claim 1, wherein the plurality of electrode films are formed by at least one of copper or tungsten.

11. The semiconductor storage device according to claim 1, wherein the first insulating films are formed by silicon oxide.

12. The semiconductor storage device according to claim 1, wherein the semiconductor layer is a source layer.

13. The semiconductor storage device according to claim 1, wherein the wiring is formed of at least copper or tungsten.

14. The semiconductor storage device according to claim 2,
wherein the third insulating film contains at least silicon and oxygen.

15. The semiconductor storage device according to claim 3,
wherein the third insulating film contains at least silicon and oxygen.

16. The semiconductor storage device according to claim 2,
wherein the third insulating film contains at least silicon, oxygen, and fluorine.

17. The semiconductor storage device according to claim 3,
wherein the third insulating film contains at least silicon, oxygen, and fluorine.
